(19) United States
(12) Patent Application Publication
(10) Pub. No.: US 2024/0124234 A1
(43) Pub. Date: Apr. 18, 2024

(54) COMPONENT WAREHOUSING SUPPORT APPARATUS, COMPONENT WAREHOUSING SUPPORT METHOD, COMPONENT WAREHOUSING SUPPORT PROGRAM, AND RECORDING MEDIUM

(71) Applicant: YAMAHA HATSUDOKI KABUSHIKI KAISHA, Iwata-shi, Shizuoka (JP)

(72) Inventor: Yoichi MATSUSHITA, Iwata-shi (JP)

(73) Assignee: YAMAHA HATSUDOKI KABUSHIKI KAISHA, Iwata-shi, Shizuoka (JP)

(21) Appl. No.: 18/554,399

(22) PCT Filed: May 26, 2021
(86) PCT No.: PCT/JP2021/019997

§ 371 Date: Oct. 6, 2023

(51) Int. Cl. B65G 1/137; H05K 13/02

(52) U.S. Cl. CPC B65G 1/1371; H05K 13/02

(57) ABSTRACT

In a component warehousing support apparatus, the stock quantity which is the number of target components to be warehoused, which are actually stored in each of component storages, is acquired for each of the plurality of component storages. Then, the warehousing destination candidate information indicating a candidate of the warehousing destination of the target component among the plurality of component storages is calculated on the basis of the stock quantity of the target component in each of the plurality of the component storages. Therefore, a candidate of the warehousing destination in accordance with the stock quantity of the target component in each component storage can be confirmed with reference to the warehousing destination candidate information. As a result, it becomes possible to easily determine an appropriate component storage as the warehousing destination of the component from among the plurality of component storages.

### CROSS-REFERENCE TO RELATED APPLICATION

This application is a National Stage of International Patent Application No. PCT/JP2021/019997, filed May 26, 2021, the entire contents of which is incorporated herein by reference.

### BACKGROUND

### Technical Field

The present disclosure relates to a technology for supporting warehousing of components into a plurality of component storages which store warehoused components and deliver the components in response to a request from the outside.

### BACKGROUND ART

A component mounter producing a component-mounted board by mounting a component supplied by a feeder on a board by using a mounting head is well known. On such a component mounter, a component needs to be set when board production is started or component shortage occurs in the middle of board production. Further, Japanese Patent Application Laid Open Gazette No. 2018-164017 proposes a component storage for storing components to be set on the component mounter for board production. This component storage stores components warehoused by an operator and delivers the components in response to a request of the operator. Therefore, the operator can warehouse a component required for the board production into the component storage in advance, deliver the component at a timing when the component is needed and set the component on the component mounter.

### SUMMARY

For the purpose of securing components to be stored for board production, or the like, there is a possible case where a plurality of component storages are used. In such a case, however, it is difficult to determine which of the plurality of component storages is an appropriate one into which components to be warehoused should be warehoused.

Accordingly, the present disclosure makes it possible to easily determine an appropriate component storage as a warehousing destination of a component from among a plurality of component storages.

A component warehousing support apparatus which supports warehousing of a component into each of a plurality of component storages in which a warehoused component is stored and from which a component is delivered in response to a request. The component warehousing support apparatus comprises a stock quantity acquisition part configured to acquire a stock quantity indicating a number of target components to be warehoused, which are actually stored in each of the component storages, for each of the plurality of component storages; and a warehousing destination candidate calculation part configured to calculate warehousing destination candidate information indicating a candidate of a warehousing destination of the target component from among the plurality of component storages, on the basis of the stock quantity of the target component in each of the plurality of component storages.

A component warehousing support method which supports warehousing of a component into each of a plurality of component storages in which a warehoused component is stored and from which the component is delivered in response to a request. The method comprises acquiring a stock quantity indicating the number of target components to be warehoused, which are actually stored in each of the component storages, for each of the plurality of component storages; and calculating warehousing destination candidate information indicating a candidate of a warehousing destination of the target component from among the plurality of component storages, on the basis of the stock quantity of the target component in each of the plurality of component storages.

A component warehousing support program which supports warehousing of a component into each of a plurality of component storages in which a warehoused component is stored and from which the component is delivered in response to a request. The component warehousing support program causes a computer to execute the steps of: acquiring a stock quantity indicating the number of target components to be warehoused, which are actually stored in each of the component storages, for each of the plurality of component storages; and calculating warehousing destination candidate information indicating a candidate of a warehousing destination of the target component from among the plurality of component storages, on the basis of the stock quantity of the target component in each of the plurality of component storages.

A recording medium records therein the component warehousing support program according to the above in a computer-readable manner.

In the present disclosure (the component warehousing support apparatus, the component warehousing support method, the component warehousing support program, and the recording medium) having such a configuration, a stock quantity indicating the number of target components to be warehoused, which are actually stored in each of component storages, is acquired for each of the plurality of component storages. Then, warehousing destination candidate information indicating a candidate of a warehousing destination of the target component from among the plurality of component storages is calculated on the basis of the stock quantity of the target component in each of the plurality of component storages. Therefore, it is possible to check the candidate of the warehousing destination in accordance with the stock quantity of the target component in each of the component storages, from the warehousing destination candidate information. As a result, it becomes possible to easily determine an appropriate component storage as the warehousing destination of the component from among the plurality of component storages.

Further, as a subject who determines the warehousing destination of the component, considered is an operator, a work robot, or the like who performs warehousing and delivery into/from the component storage.

The component warehousing support apparatus may be configured so that the warehousing destination candidate information indicates each of the plurality of component storages as the candidate, with priority calculated on the basis of the stock quantity of the target component in each of the plurality of component storages. It is thereby possible to select the warehousing destination of the target component from among the plurality of component storages with reference to the priority of each of the plurality of component storages.

The component warehousing support apparatus may be configured so that the warehousing destination candidate calculation part determines the priority on the basis of a result obtained by calculating a difference between an ideal number which is the ideal number of target components stored in the component storages and the stock quantity of the target component, for each of the plurality of component storages. With such a configuration, it is possible to support the warehousing of the target component so that the number of target components to be stored in the component storage can get closer to the ideal number.

The component warehousing support apparatus may be configured so that the warehousing destination candidate calculation part calculates an average value of the stock quantities of the target component in the plurality of component storages, as the ideal number of the target component which is common to the plurality of component storages. With such a configuration, it is possible to support the warehousing of the target component so that the respective numbers of target components stored in the plurality of component storages can become even. For this reason, when the target component is needed, for example, it is possible to deliver the target components from the plurality of component storages in parallel. Therefore, it is possible to complete the delivery of the target components in the necessary number in a short time.

The component warehousing support apparatus may be configured so that the warehousing destination candidate calculation part acquires a plurality of production plans each for producing a predetermined type of component-mounted board by mounting a component on a board, associates the plurality of production plans with different component storages, respectively, and calculates the ideal number of the target component in the component storage on the basis of the number of target components to be mounted on the boards in the production plan corresponding to the component storage. With such a configuration, by associating the plurality of production plans with different component storages, it is possible to warehouse the target component into the component storage corresponding to the production plan in which the target component is to be used. Thus, it is possible to use different component storage depending on the production plans. For this reason, it is possible to avoid such a condition in which the delivery of the component needed for each of the plurality of production plans which are executed in parallel is concentrated on the same component storage and therefore the delivery of the components is delayed.

The component warehousing support apparatus may be configured so that the warehousing destination candidate calculation part acquires details of a setup operation for setting a component at each of a plurality of component setting positions included in a component supply trolley, at each of which the component is settable, divides the plurality of component setting positions into a plurality of divisions corresponding to the different component storages, and calculates the ideal number of the target component in the component storage on the basis of the number of target components to be set at the component setting positions belonging to the division corresponding to the component storage. With such a configuration, the plurality of component setting positions of the component supply trolley are divided into a plurality of divisions and the divisions are associated with different component storages. Then, it is possible to warehouse the target component into the component storage corresponding to the division including the component setting position at which the target component is to be set. For this reason, it is possible to deliver the components to be set on the component supply trolley in the setup operation, from the plurality of component storages in parallel. Therefore, it is possible to complete the delivery of each component required for the setup operation in a short time.

The component warehousing support apparatus may be configured so that the warehousing destination candidate calculation part calculates the ideal number of the target component in the component storage on the basis of a result obtained by calculating the number of components to be stored into each of the plurality of component storages on the basis of a plan to store in advance two component holding members in different component storages. The two component holding members are to be replenished to a feeder in response to two-times component shortages expected to occur in succession when a component held by a component holding member holding a component is supplied by each of a plurality of feeders and mounted on a board. With such a configuration, it is possible to avoid such a condition in which the delivery of each component of which shortage occurs in succession is requested to the same component storage and the delivery of the component is delayed.

The component warehousing support apparatus may be configured so that the warehousing destination candidate information indicates one optimal component storage as the candidate of the warehousing destination among the plurality of component storages. With such a configuration, it is possible to easily determine one optimal component storage as the warehousing destination of the component from among the plurality of component storages.

The component warehousing support apparatus may further comprise a display part that displays the candidate of the warehousing destination of the target component, which is indicated by the warehousing destination candidate information, from among the plurality of component storages, to an operator. With such a configuration, the operator checks the display part and can thereby easily determine an appropriate component storage as the warehousing destination of the component from among the plurality of component storages.

According to the present disclosure, it becomes possible to easily determine an appropriate component storage as a warehousing destination of a component from among a plurality of component storages.

### BRIEF DESCRIPTION OF THE DRAWINGS

FIG. 1 is a block diagram showing a component mounting system equipped with a server computer which corresponds to one example of a component warehousing support apparatus in accordance with the present disclosure;

FIG. 2 is a perspective view schematically showing a configuration of a component storage;

FIG. 3 is a plan view schematically showing a configuration of a component mounter;

FIG. 4 is a flowchart showing a first example of a component warehousing support;

FIG. 5 is a flowchart showing a first warehousing support executed in the component warehousing support shown in FIG. 4;

FIG. 6A is a view schematically showing a stock quantity of a target component in each component storage;

FIG. 6B is a view schematically showing a setting example of the priority based on a difference between the stock quantity and an ideal number in the component storage;

FIG. 6C is a view schematically showing an example of a support screen in the first warehousing support;

FIG. 7 is a flowchart showing a second warehousing support executed in the component warehousing support shown in FIG. 4;

FIG. 8A is a view schematically showing details of a production plan for each of a plurality of mounting lines;

FIG. 8B is a view schematically showing a correspondence between a type and a mounting program used for production of this type of component-mounted board;

FIG. 8C is a view schematically showing a correspondence between a component and a usage quantity of the component;

FIG. 9A is a view schematically showing the stock quantity of a target component in each component storage;

FIG. 9B is a view schematically showing a setting example of the priority based on a difference between the stock quantity and the ideal number in the component storage;

FIG. 9C is a view schematically showing an example of a support screen in the second warehousing support;

FIG. 10 is a flowchart showing a second example of a component warehousing support;

FIG. 11 is a flowchart showing a third warehousing support executed in the component warehousing support shown in FIG. 10;

FIG. 12A is a view schematically showing one example of a division mode of a plurality of reel setting positions of a component supply trolley;

FIG. 12B is a view schematically showing the stock quantity of a target component in each component storage;

FIG. 12C is a view schematically showing a setting example of the priority based on a difference between the stock quantity and the ideal number in the component storage;

FIG. 12D is a view schematically showing an example of a support screen in the third warehousing support;

FIG. 13 is a flowchart showing a fourth warehousing support executed in the component warehousing support shown in FIG. 10;

FIG. 14A is a view schematically showing an exemplary case of setting a storage destination of a component on the basis of a storage plan in accordance with the order of occurrence of component shortage;

FIG. 14B is a view schematically showing an example of the number of components planned to be replenished from the plurality of component storages;

FIG. 14C is a view schematically showing an example of a surplus stock quantity of a component in each of the plurality of component storages;

FIG. 14D is a view schematically showing the surplus stock quantity of a target component in each component storage;

FIG. 14E is a view schematically showing a setting example of the priority based on a difference between the surplus stock quantity and the ideal number of the target component in the component storage; and

FIG. 14F is a view schematically showing an example of a support screen in the fourth warehousing support.

### DETAILED DESCRIPTION

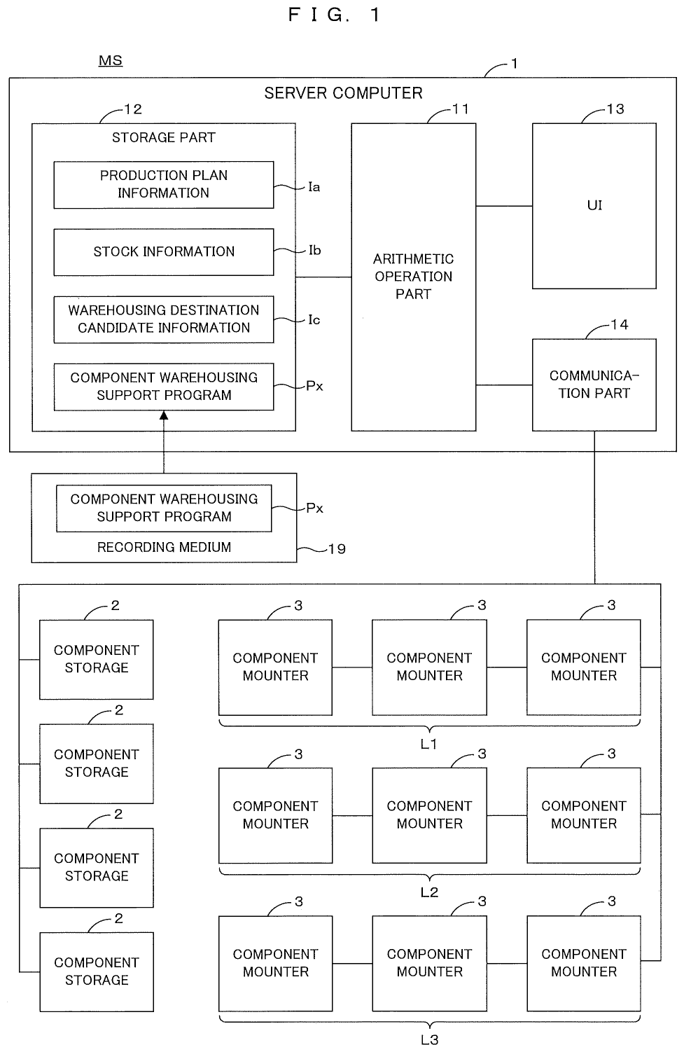

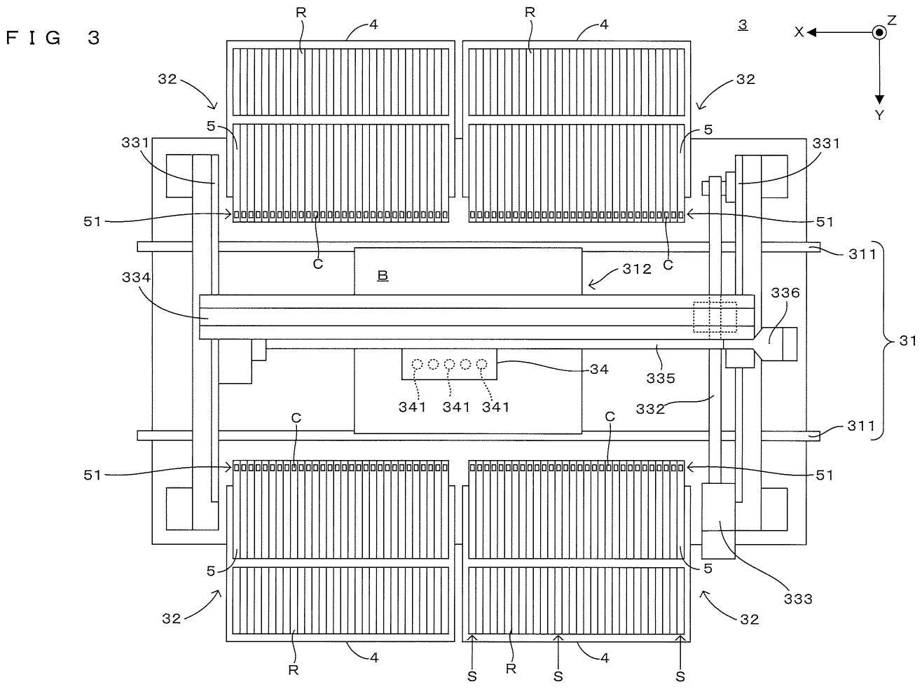

FIG. 1 is a block diagram showing a component mounting system equipped with a server computer which corresponds to one example of a component warehousing support apparatus in accordance with the present disclosure. The component mounting system MS includes a server computer 1, a plurality of component storages 2, and a plurality of component mounters 3, and the server computer 1 controls each of the plurality component storages 2 and the component mounters 3. Though four component storages 2 are provided in this exemplary case, the number of component storages 2 is not limited to four. Further, provided are three production lines L1, L2, and L3 each constituted of three component mounters 3, and in each of the production lines L1, L2, and L3, a board B (FIG. 3) is transferred sequentially to the three component mounters 3 which are arranged in series and each of the three component mounters 3 mounts a component C (FIG. 3) on the board B. Thus, each of the production lines L1, L2, and L3 produces a component-mounted board of the type which each production line is in charge of. Furthermore, the number of production lines L1 to L3 or the number of component mounters 3 constituting each of the production lines L1 to L3 is not limited to this example.

The server computer 1 includes an arithmetic operation part 11, a storage part 12, a UI (User Interface) 13, and a communication part 14. The arithmetic operation part 11 is a processor constituted of a CPU (Central Processing Unit) and a memory, and controls the storage part 12, the UI 13, and the communication part 14. The storage part 12 is formed of an HDD (Hard Disk Drive), an SSD (Solid State Drive), or the like, and stores therein a component warehousing support program Px defining details of a component warehousing support and various information Ia to Ic. Further, the server computer 1 reads the component warehousing support program Px recorded in a recording medium 19 such as a USB (Universal Serial Bus) memory, an optical disk, or the like and stores the program Px into the storage part 12. The mode of acquiring the component warehousing support program Px is not limited to this exemplary case, and the server computer 1 may download the component warehousing support program Px recorded in a memory device of an external computer and stores the program Px into the storage part 12.

The UI 13 has an output device such as a display or the like which displays information to an operator and an input device such as a keyboard, a mouse, or the like which receives an input operation by the operator. Further, it is not necessary to separately provide the output device and the input device of the UI 13, and the output device and the input device may be integrally provided by using a touch panel display to form the UI 13. Further, the communication part 14 performs communication with external devices such as the component storages 2 and the component mounters 3.

As a specific mode of the server computer 1, a desktop computer, a laptop computer, a tablet computer, or the like may be adopted. In a case where the server computer 1 is formed of a tablet computer, the operator can perform the operation while carrying the server computer 1.

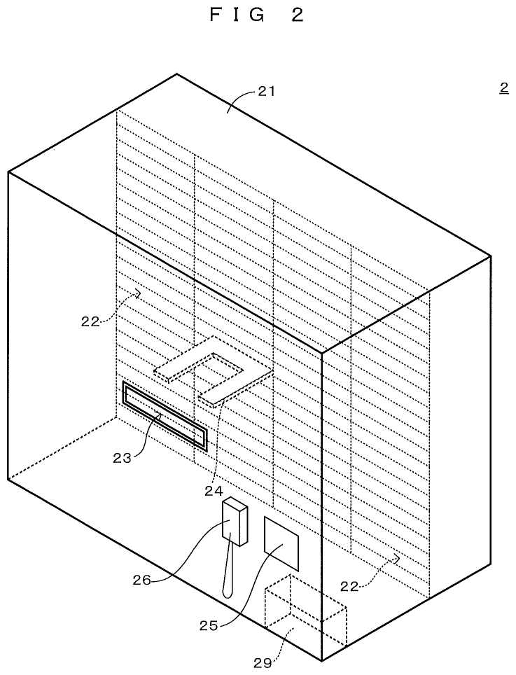

FIG. 2 is a perspective view schematically showing a configuration of the component storage. The component storage 2 has a housing 21 and a plurality of shelfs 22 provided inside the housing 21, and a component supply reel R (FIG. 3) for holding the components C is stored in each of the shelfs 22. A carrier tape having a plurality of pockets which are arranged in series is wound around the component supply reel R, and the components C are accommodated in these pockets. A specific example of the component C includes a chip-like electronic component such as an integrated circuit, a transistor, a capacitor, or the like. Further, to the component supply reel R, attached is a component ID indicating the type of the component C or the number of components C held by the component supply reel R.

Further, the component storage 2 includes an opening 23 provided on a front surface of the housing 21 and a handler 24 transferring the component supply reel R. The handler 24 moves inside the housing 21 while holding the component supply reel R, to thereby transfer the component supply reel R between the opening 23 and the handler 24. Furthermore, the component storage 2 includes an operation panel 25 receiving an input operation by the operator, a scanner 26 reading the component ID attached to the component supply reel R, and a control part 29 controlling the operation panel 25 and the scanner 26.

The operation panel 25 receives a warehousing instruction for instructing the warehousing of the component supply reel R or a delivery instruction for instructing the delivery of the component supply reel R. In the warehousing, the operator inputs the warehousing instruction to the operation panel 25 and inserts the component supply reel R to be warehoused into the opening 23, and the handler 24 accommodates the component supply reel R inserted into the opening 23, into the shelf 22 (warehousing). Further, before inserting the component supply reel R into the opening 23, the operator causes the scanner 26 to read the component ID attached to the component supply reel R and the scanner 26 transmits the component ID which is read, to the control part 29. The control part 29 can thereby acquire the component ID of the component supply reel R warehoused into the component storage 2. In the delivery, the operator inputs the delivery instruction for the component supply reel R to be delivered, to the operation panel 25, and the handler 24 takes the component supply reel R indicated by the delivery instruction out of the shelf 22 and discharges the component supply reel R to the opening 23 (delivery).

Every time when the warehousing or the delivery to/from the component storage 2 is performed, warehousing and delivery information indicating the component ID of the component supply reel R to be warehoused or delivered is transmitted from the control part 29 of the component storage 2 to the communication part 14 of the server computer 1. Then, the arithmetic operation part 11 of the server computer 1 updates stock information Ib indicating a stock of the component C in the component storage 2 on the basis of the warehousing and delivery information received by the communication part 14.

FIG. 3 is a plan view schematically showing a configuration of the component mounter. This figure shows an XYZ rectangular coordinate system with an X direction and a Y direction each parallel to a horizontal direction and with a Z direction parallel to a vertical direction.

The component mounter 3 includes a board transfer part 31 transferring the board B in the X direction (board transfer direction). This board transfer part 31 has a pair of conveyors 311 arranged in parallel in the X direction and transfers the board B in the X direction by the conveyors 311. An interval between these conveyors 311 can be changed in the Y direction (width direction) orthogonal to the X direction, and the board transfer part 31 adjusts the interval of the conveyors 311 in accordance with the width of the board B to be transferred. This board transfer part 31 loads the board B to a predetermined mounting operation position 312 from an upstream side in the X direction which is the board transfer direction and unloads the board B on which the component C is mounted at the mounting operation position 312 from the mounting operation position 312 to a downstream side in the X direction.

Two trolley mounting parts 32 are aligned in the X direction on each side of the Y direction of the board transfer part 31, and to each of the trolley insertion parts 32, the component supply trolley 4 can be attached in a detachable/attachable manner. In the trolley insertion part 32 to which the component supply trolley 4 is attached, a plurality of tape feeders 5 held by the component supply trolley 4 are aligned in the X direction. Further, the component supply trolley 4 is provided with a plurality of reel setting positions S corresponding to the plurality of tape feeders 5, and the component supply reel R is allocated to each reel setting position S. Thus, the component supply trolley 4 holds the plurality of component supply reels R set to the plurality of reel setting positions S, respectively. Each tape feeder 5 transfers the carrier tape drawn from the corresponding component supply reel R to the side of the board transfer part 31. On the other hand, a component supply position 51 is provided at a tip portion of the side of the board transfer part 31 of each tape feeder 5, and the plurality of components C accommodated in the carrier tape are sequentially supplied to the component supply positions 51.

The component mounter 3 is provided with a pair of Y-axis rails 331 extending in the Y direction, a Y-axis ball screw 332 extending in the Y direction, and a Y-axis motor 333 which rotationally drives the Y-axis ball screw 332. Then, the pair of Y-axis rails 331 support an X-axis beam 334 extending in the X direction, movably in the Y direction, and the X-axis beam 334 is fixed to a nut of the Y-axis ball screw 332. To the X-axis beam 334, attached are an X-axis ball screw 335 extending in the X direction and an X-axis motor 336 which rotationally drives the X-axis ball screw 335. The X-axis beam 334 supports a head unit 34 movably in the X direction, and the head unit 34 is fixed to a nut of the X-axis ball screw 335. Therefore, the head unit 34 can be moved in the Y direction when the Y-axis motor 333 rotates the Y-axis ball screw 332, and the head unit 34 can be moved in the X direction when the X-axis motor 336 rotates the X-axis ball screw 335.

The head unit 34 has a plurality of mounting heads 341 aligned in the X direction. Each of the mounting heads 341 mounts the component C on the board B by using a nozzle attached to a lower end thereof in a detachable/attachable manner. Specifically, the mounting head 341 causes the nozzle at the lower end thereof to be positioned above the component supply position 51 and go down the nozzle to brings the nozzle into contact with the component C to be supplied to the component supply position 51 by the tape feeder 5. Then, the mounting head 341 gives a negative pressure into a nozzle, to thereby cause the nozzle to adsorb the component C, and causes the nozzle to go up. Thus, the mounting head 341 causes the component C picked up from the component supply position 51 to move to above the board B at the component supply position 51 while adsorbing and holding the component C by using the nozzle. Then, when the mounting head 341 causes the nozzle to go down, to thereby bring the component C into contact with the board B, the mounting head 341 releases the negative pressure of the nozzle and place the component C on the board B.

Subsequently, details of the component warehousing support will be described. Further, the component warehousing support described below gives information to the operator, which the operator needs to determine the warehousing destination of the component C to be warehoused from now on (i.e., the target component C to be warehoused). Further, the warehousing of the component C is performed by warehousing the component supply reel R holding the component C into component storage 2.

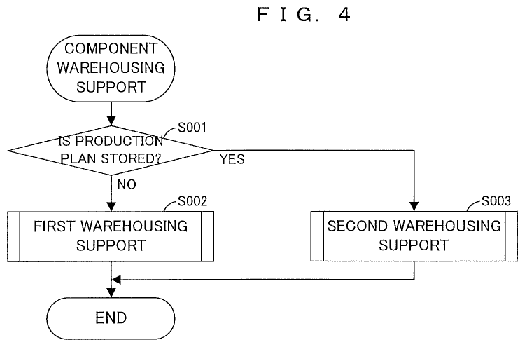

FIG. 4 is a flowchart showing a first example of a component warehousing support. This flowchart is executed by a control of the arithmetic operation part 11. As shown in FIG. 4, the arithmetic operation part 11 checks if production plan information Ia is stored in the storage part 12 as the component warehousing support starts (Step S001). The production plan information Ia indicates details of a production plan to be executed in each of the production lines L1 to L3, and each of the production lines L1 to L3 causes the component mounters 3 to perform an operation defined by the corresponding production plan, to thereby produce a predetermined type of component-mounted board.

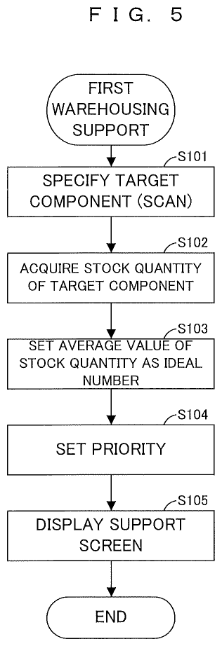

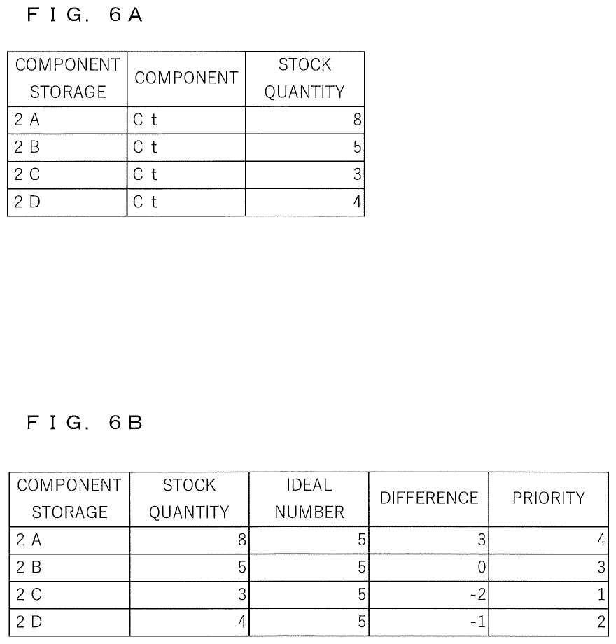

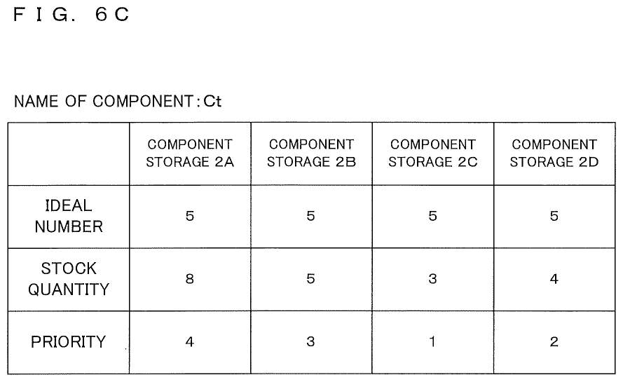

When the production plan information Ia is not stored in the storage part 12 (“NO” in Step S001), a first warehousing support is executed in Step S002 (FIG. 5). Herein, FIG. 5 is a flowchart showing the first warehousing support executed in the component warehousing support shown in FIG. 4. For warehousing the component C, the operator causes the scanner 26 to read the component ID attached to the component supply reel R holding the component C. In contrast to this, in Step S101 for the first warehousing support, the arithmetic operation part 11 acquires the component ID read by the scanner 26 and specifies the target component Ct to be warehoused, on the basis of this component ID. The arithmetic operation part 11 can thereby recognize the type of target component Ct. In Step S102, the arithmetic operation part 11 acquires a stock quantity of the target component Ct in each of the plurality of component storages 2 on the basis of the stock information Ib stored in the storage part 12 (FIG. 6A).

FIG. 6A is a view schematically showing the stock quantity of the target component in each component storage. In FIG. 6A, different reference sings 2A to 2D are used for distinguishing the plurality of component storages 2 from one another, and the stock quantity of the target component Ct is represented by the number of component supply reels R for holding the target components Ct. In the exemplary case shown in FIG. 6A, the respective stock quantities of the component supply reels R for the target components Ct in the component storages 2A, 2B, 2C, and 2D are 8, 5, 3, and 4. Further, unless otherwise specified, also hereinafter, the number of component supply reels R holding the components C is used as a unit indicating the number of components C.

In Step S103, the arithmetic operation part 11 sets an ideal number of the target component Ct in each of the plurality of component storages 2A to 2D. Herein, the ideal number refers to the ideal number of target components Ct stored in each of the component storages 2A to 2D. In the first warehousing support, an average value of the stock quantities of the target component Ct in the plurality of component storages 2A to 2D is set as the ideal number. Specifically, in the exemplary case shown in FIG. 6A, an average value of the target component Ct (5=(8+5+3+4)/4) is set as the ideal number. In Step S104, the arithmetic operation part 11 sets priorities for the component storages 2A to 2D on the basis of the difference (=stock quantity−ideal number) between the stock quantity and the ideal number of the target component Ct in each of the component storages 2A to 2D. Specifically, as the value obtained by subtracting the ideal number from the stock quantity in the component storage 2 becomes smaller, in other words, as a shortage of the stock quantity relative to the ideal number in the component storage 2 becomes larger, higher priority is set to the component storage 2 (FIG. 6B).

FIG. 6B is a view schematically showing a setting example of the priority based on the difference between the stock quantity and the ideal number in the component storage. FIG. 6B shows the stock quantity, the ideal number, the difference, and the priority for each of the component storages 2A to 2D, and the respective priorities of the component storages 2A, 2B, 2C, and 2D are 4, 3, 1, and 2. This priority indicates which one of the component storages 2A to 2D should be prioritized in the warehousing of the target component Ct. In other words, the information shown in FIG. 6B corresponds to warehousing destination candidate information Ic indicating a candidate of the warehousing destination of the target component Ct among the plurality of component storages 2A to 2D, and this warehousing destination candidate information Ic is calculated by the arithmetic operation part 11 in the above-described procedure and stored into the storage part 12.

In Step S105, the arithmetic operation part 11 creates a support screen used for supporting the warehousing by the operator on the basis of the warehousing destination candidate information Ic and displays the support screen on a display of the UI 13 (FIG. 6C). FIG. 6C is a view schematically showing an example of the support screen in the first warehousing support. This support screen shows an arithmetic operation result obtained in Steps S103 and S104, and specifically, displays the ideal number and the stock quantity of the target component Ct in each of the component storages 2A to 2D and the priorities of the component storages 2A to 2D as the warehousing destination of the target component Ct.

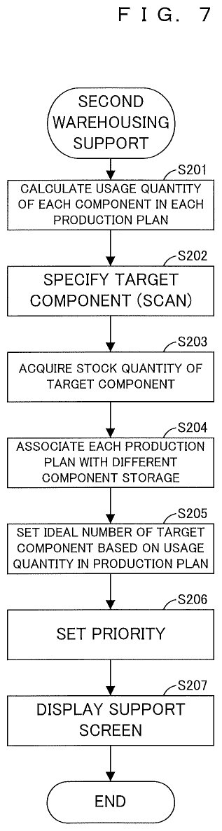

The details of the first warehousing support have been shown above. On the other hand, in Step S001 of FIG. 4, when the production plan information Ia stored in the storage part 12 is confirmed (“YES”), a second warehousing support is executed in Step S003 (FIG. 7). Herein, FIG. 7 is a flowchart showing the second warehousing support executed in the component warehousing support shown in FIG. 4. In Step S201, the arithmetic operation part 11 calculates the usage quantity of each component C in each production plan.

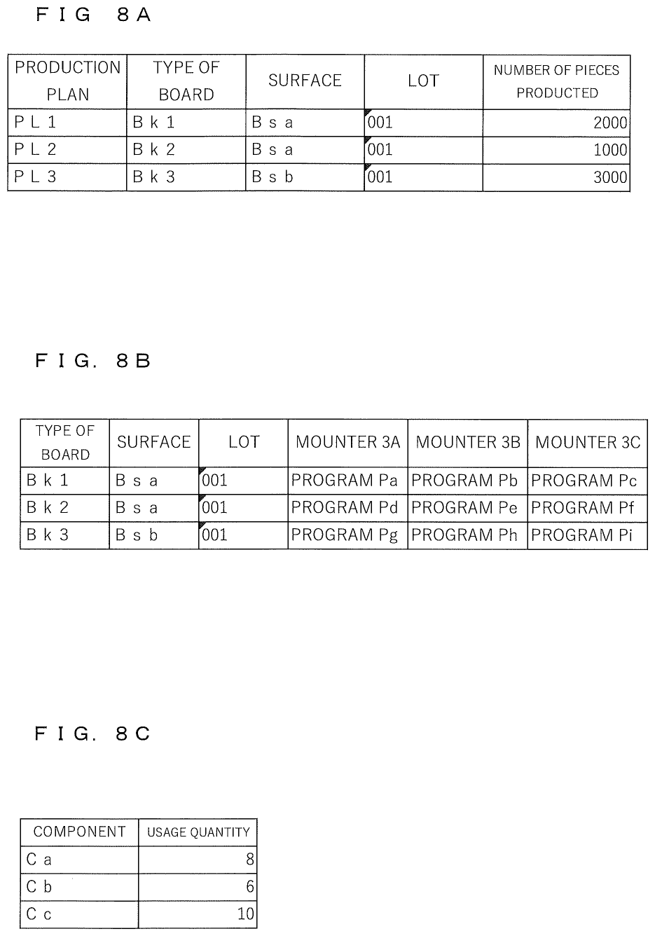

Specifically, the arithmetic operation part 11 specifies each of production plans PL1 to PL3 included in the production plan information Ia (FIG. 8A). Herein, FIG. 8A is a view schematically showing details of a production plan for each of a plurality of mounting lines. The plurality of production plans PL1, PL2, and PL3 shown in FIG. 8A are executed in the plurality of production lines L1,L2, and L3, respectively. According to the production plan PL1, for example, when each component mounter 3 in the production line L1 mounts a component C on a surface Bsa among two surfaces Bsa and Bsb of a board B having a lot number of “001”, 2000 component-mounted boards of the type BK1 are produced.

Further, the arithmetic operation part 11 specifies mounting programs Pa to Pi to be used for production of each type of component-mounted board (FIG. 8B). Herein, FIG. 8B is a view schematically showing a correspondence between a type and the mounting program used for production of this type of component-mounted board. In FIG. 8B, different reference sings 3A to 3C are used for distinguishing the three component mounters 3 constituting one production line L from one another. The mounting program refers to a program defining a procedure in which the component mounter 3 mounts a component C on a board B, and the component mounter 3 operates in accordance with the mounting program, to thereby mount the component C on a predetermined portion of the board B. According to FIG. 8B, for production of a component-mounted board of the type BK1, for example, the three component mounters 3A, 3B, and 3C in the production line L1 mount components C on a board B in accordance with the mounting programs Pa, Pb, and Pc, respectively.

Each of the mounting programs Pa, Pb, and Pc indicates the number of components C to be mounted on the board B, for each type of component C, for production of one component-mounted board of the type BK1 to be produced in the production line L1. The arithmetic operation part 11 calculates the number of components C of each type to be mounted in the production plan PL1 executed in the production line L1 by multiplying the number of components C to be mounted for one component-mounted board by the production quantity of the component-mounted board of the type BK1. Further, the arithmetic operation part 11 calculates the number (usage quantity) of component supply reels R for holding the components C required to execute the production plan PL1 by dividing the number of components C to be mounted by the number of components C held by the component supply reel R (FIG. 8C). FIG. 8C is a view schematically showing a correspondence between a component C and the usage quantity of the component. In the exemplary case shown in FIG. 8C, the respective numbers of components Ca, Cb, and Cc (the number of component supply reels R) to be used for production of the component-mounted board of the type BK1 on the basis of the production plan PL1 in the production line L1 are 8, 6, and 10. The usage quantity of the component C (the number of component supply reels R) is obtained also for each of the production plans PL2 and PL3 in the same manner.

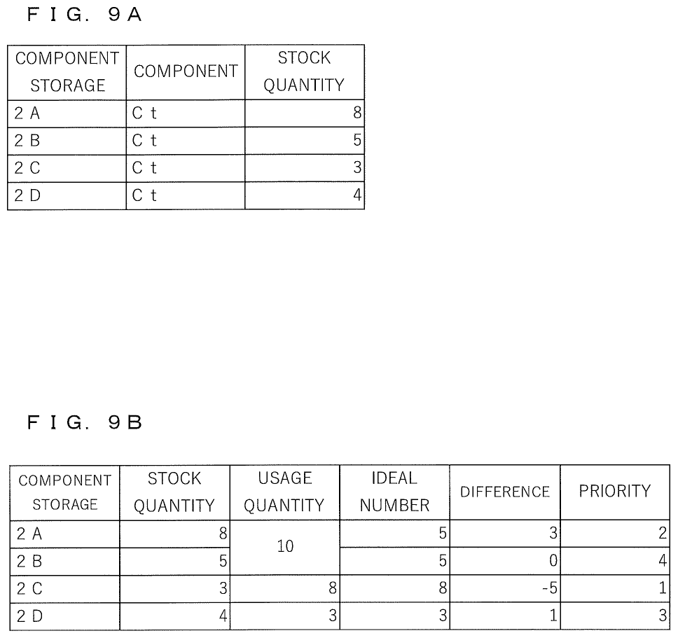

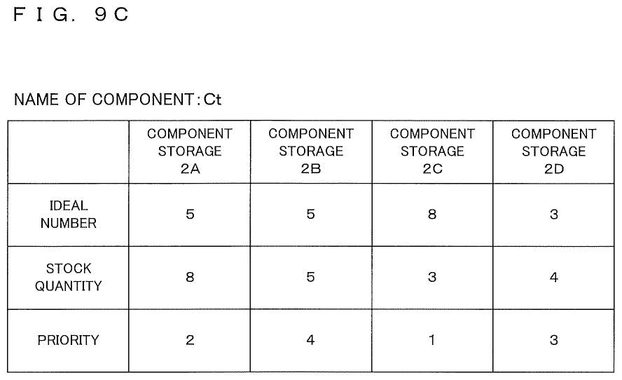

In Step S202, the arithmetic operation part 11 specifies a target component Ct to be warehoused, on the basis of the component ID read by the scanner 26. The arithmetic operation part 11 can thereby recognize the type of target component Ct. In Step S203, the arithmetic operation part 11 acquires the stock quantity of the target component Ct in each of the plurality of component storages 2, on the basis of the stock information Ib stored in the storage part 12 (FIG. 9A).

FIG. 9A is a view schematically showing the stock quantity of the target component in each component storage. In FIG. 9A, different reference sings 2A to 2D are used for distinguishing the plurality of component storages 2 from one another, and the stock quantity of the target component Ct is represented by the number of component supply reels R holding the target components Ct. In the exemplary case shown in FIG. 9A, the respective stock quantities of the component supply reel R holding the target component Ct in the component storages 2A, 2B, 2C, and 2D are 8, 5, 3, and 4.

In Step S204, the arithmetic operation part 11 associates the plurality of production plans PL1 to PL3 with different component storages 2. In this example, the production plan PL1 is associated with two component storages 2A and 2B, the production plan PL2 is associated with one component storage 2C, and the production plan PL3 is associated with one component storage 2D. Then, the arithmetic operation part 11 sets the ideal number on the basis of the usage quantity of the target component Ct in the production plans PL1 to PL3 (Step S205), and sets the priorities to the component storages 2A to 2D on the basis of the difference (=stock quantity−ideal number) between the stock quantity and the ideal number. Specifically, as the value obtained by subtracting the ideal number from the stock quantity in the component storage 2 becomes smaller, in other words, as a shortage of the stock quantity relative to the ideal number in the component storage 2 becomes larger, higher priority is set to the component storage 2 (FIG. 9B).

FIG. 9B is a view schematically showing a setting example of the priority based on the difference between the stock quantity and the ideal number in the component storage. In the second warehousing support, a value obtained by dividing the usage quantity of the target component Ct in the production plan by the number of component storages 2 corresponding to the production plan is set as the ideal number. Specifically, in the exemplary case shown in FIG. 9B, since the number (usage quantity) of target components Ct to be used in the production plan PL1 is 10, a value (=5) obtained by dividing the usage quantity (=10) by the number (=2) of component storages 2A and 2B corresponding to the production plan PL1 is set as the ideal number of the target component Ct for each of the component storages 2A and 2B. Further, since the number (usage quantity) of target components Ct to be used in the production plan PL2 is 8, a value (=8) obtained by dividing the usage quantity (=8) by the number (=1) of component storage 2C corresponding to the production plan PL2 is set as the ideal number of the target component Ct for the component storage 2C. The ideal number of the target component Ct in the component storage 2D corresponding to the production plan PL3 is also set in the same manner. Then, the respective differences between the stock quantity and the ideal number in the component storages 2A, 2B, 2C, and 2D are obtained as 3, 0, −5, and 1, and as the value obtained by subtracting the ideal number from the stock quantity in the component storage 2 becomes smaller, in other words, as a shortage of the stock quantity relative to the ideal number in the component storage 2 becomes larger, higher priority is set to the component storage 2. As a result, the respective priorities of the component storages 2A, 2B, 2C, and 2D becomes 2, 4, 1, and 3. In other words, the information shown in FIG. 9B corresponds to the warehousing destination candidate information Ic indicating a candidate of the warehousing destination of the target component Ct among the plurality of component storages 2A to 2D, and this warehousing destination candidate information Ic is calculated by the arithmetic operation part 11 in the above-described procedure and stored into the storage part 12.

In Step S207, the arithmetic operation part 11 creates the support screen used for supporting the warehousing by the operator, on the basis of the warehousing destination candidate information Ic, and displays the support screen on the display of the UI 13 (FIG. 9C). FIG. 9C is a view schematically showing an example of the support screen in the second warehousing support. This support screen shows an arithmetic operation result obtained in Steps S203 and S205, and specifically, displays the ideal number and the stock quantity of the target component Ct in each of the component storages 2A to 2D and the priorities of the component storages 2A to 2D as the warehousing destination of the target component Ct.

In the above-described embodiment, the stock quantity which is the number of target components Ct to be warehoused, which are actually stored in each of component storages 2A to 2D, is acquired for each of the plurality of component storages 2A to 2D (Steps S102 and S203). Then, the warehousing destination candidate information Ic (FIGS. 6B and 9B) indicating a candidate of the warehousing destination of the target component Ct among the plurality of component storages 2A to 2D is calculated on the basis of the stock quantity of the target component Ct in each of the plurality of the component storages 2A to 2D (Steps S103 to S104 and S204 to S206). Therefore, a candidate of the warehousing destination in accordance with the stock quantity of the target component Ct in each component storage 2 can be confirmed with reference to the warehousing destination candidate information Ic. As a result, it becomes possible to easily determine an appropriate component storage 2 as the warehousing destination of the component C from among the plurality of component storages 2a to 2D.

Further, the warehousing destination candidate information Ic indicates each of the plurality of component storages 2A to 2D as the candidate while giving priorities thereto, the priorities being calculated on the basis of the stock quantity of the target component Ct in each of the plurality of the component storages 2A to 2D (FIGS. 6B and 9B). With reference to the priority of each of the plurality of component storages 2A to 2D, the warehousing destination of the target component Ct can be thereby selected from among the plurality of component storages 2A to 2D.

Further, the arithmetic operation part 11 (warehousing destination candidate calculation part) determines the priority on the basis of a result obtained by calculating the difference between an ideal number which is the ideal number of target components Ct stored in each of the component storages 2A to 2D and the stock quantity of the target component Ct, for each of the plurality of component storages 2A to 2D. With such a configuration, it is possible to support the warehousing of the target component Ct so that the number of target components Ct to be stored in each of the component storages 2A to 2D can get closer to the ideal number.

Furthermore, in the first warehousing support (FIG. 5), the arithmetic operation part 11 calculates an average value of the stock quantities of the target component Ct in the plurality of component storages 2A to 2D is set as the ideal number of the target component Ct common to the plurality of component storages 2A to 2D. With such a configuration, it is possible to support the warehousing of the target component Ct so that the respective numbers of target components Ct stored in the plurality of component storages 2A to 2D can become even. For this reason, when the target component Ct is needed, for example, it is possible to deliver the target components Ct from the plurality of component storages 2A to 2D in parallel. Specifically, when four component supply reels R holding the target components Ct are needed, instead of delivering four component supply reels R one by one from one component storage 2, it is possible to deliver one component supply reel R from each of the four component storages 2 in parallel. Therefore, it is possible to complete the delivery of the target components Ct in the necessary number in a short time.

Further, the arithmetic operation part 11 acquires the plurality of production plans PL1 to PL3 for production of the component-mounted boards of the types BK1 to BK3, respectively, by mounting a component C on a board B, from the storage part 12 (Step S001). Then, in the second warehousing support (FIG. 7), the arithmetic operation part 11 associates the plurality of production plans PL1 to PL3 with different component storages 2A to 2D (Step S204), and calculates the ideal number of the target component Ct in each of the component storages 2A to 2D on the basis of the number (usage quantity) of target components Ct to be mounted on the board B in the production plans PL1 to PL3 corresponding to the component storages 2A to 2D. With such a configuration, by associating the plurality of production plans PL1 to PL3 with different component storages 2A to 2D, it is possible to warehouse the target component Ct into the component storages 2A to 2D corresponding to the production plans PL1 to PL3 in which the target component Ct is to be used. Thus, it is possible to use different component storages 2 depending on the production plans PL1 to PL3. For this reason, it is possible to avoid such a condition in which the delivery of the components C needed for each of the plurality of production plans PL1 to PL3 which are executed in parallel is concentrated on the same component storage 2 and therefore the delivery of the components C is delayed.

Furthermore, provided is the UI 13 (display part) for displaying the support screen to the operator, which shows a candidate of the warehousing destination of the target component Ct indicated by the warehousing destination candidate information Ic among the plurality of component storages 2A to 2D. With such a configuration, the operator checks (the display of) the UI 13 and can thereby easily determine an appropriate component storage 2 as the warehousing destination of the component C from among the plurality of component storages 2A to 2D.

Especially, in the support screen shown in FIGS. 6C and 9C, the priorities as the warehousing destination of the target component Ct are attached to the plurality of component storages 2A to 2D. Therefore, the operator can determine the warehousing destination of the target component Ct while checking these priorities.

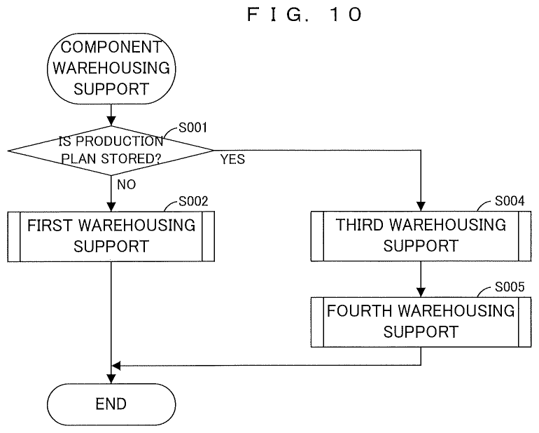

FIG. 10 is a flowchart showing a second example of the component warehousing support. This flowchart is executed by the control of the arithmetic operation part 11. As shown in FIG. 10, the arithmetic operation part 11 checks if the production plan information Ia is stored in the storage part 12 as the component warehousing support starts (Step S001). Then, when the production plan information Ia is not stored in the storage part 12 (“NO” in Step S001), the first warehousing support shown in FIG. 5 is executed in the above-described procedure (Step S002).

On the other hand, in Step S001 of FIG. 10, when the production plan information Ia stored in the storage part 12 is confirmed (“YES”), a third warehousing support is executed in Step S004 and a fourth warehousing support is executed in Step S005.

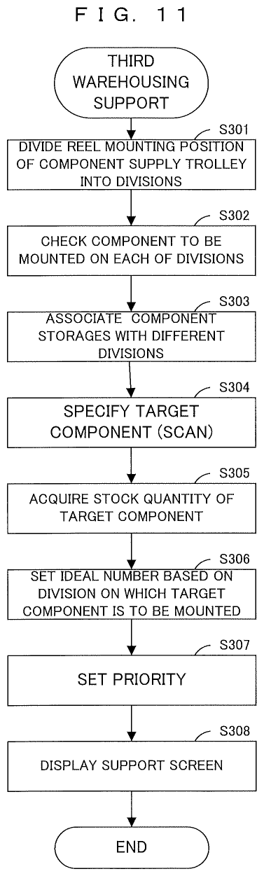

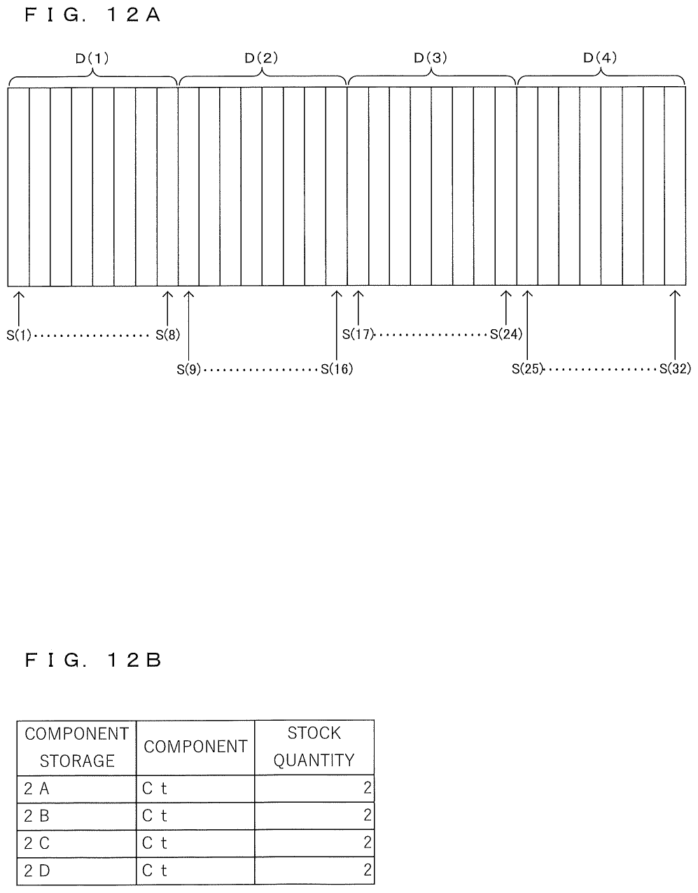

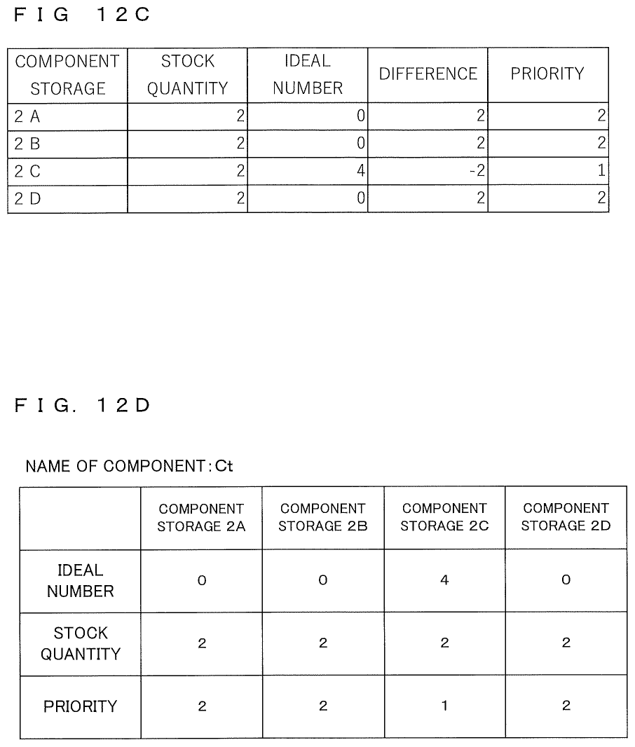

FIG. 11 is a flowchart showing the third warehousing support executed in the component warehousing support shown in FIG. 10. In Step S301, the arithmetic operation part 11 divides a plurality of reel setting positions S of the component supply trolley 4 into N divisions. Herein, “N” is “4” which is the number of component storages 2. Specifically, thirty-two reel setting position S of the component supply trolley 4 are uniformly divided into four divisions (FIG. 12A). FIG. 12A is a view schematically showing one example of a division mode of the plurality of reel setting positions of the component supply trolley. The thirty-two reel setting positions S are thereby divided into the reel setting positions S(1) to S(8) belonging to a division D(1), the reel setting positions S(9) to S(16) belonging to a division D(2), the reel setting positions S(17) to S(24) belonging to a division D(3), and the reel setting positions S(25) to S(32) belonging to a division D(4). The number “N” for division does not always need to be the number (=4) of component storages 2 provided in the component mounting system MS, and the respective numbers of reel setting positions S divided into the divisions do not always need to be even.

In Step S302, the arithmetic operation part 11 checks the component C to be set on each of the divisions D (1) to D(4). Specifically, the production plan information Ia includes setup information indicating the component C to be set at each reel setting position S of the component supply trolley 4, and the arithmetic operation part 11 checks the component C to be set on each of the divisions D(1) to D(4) on the basis of this setup information. Then, in Step S303, the arithmetic operation part 11 associates the component storages 2A, 2B, 2C, and 2D with different divisions D(1), D(2), D(3), and D(4), respectively.

In Step S304, the arithmetic operation part 11 specifies the target component Ct to be warehoused, on the basis of the component ID read by the scanner 26. The arithmetic operation part 11 can thereby recognize the type of target component Ct. In Step S305, the arithmetic operation part 11 acquires the stock quantity of the target component Ct in each of the plurality of component storages 2 on the basis of the stock information Ib stored in the storage part 12 (FIG. 12B).

FIG. 12B is a view schematically showing the stock quantity of the target component in each component storage. In FIG. 12B, different reference sings 2A to 2D are used for distinguishing the plurality of component storages 2 from one another, and the stock quantity of the target component Ct is represented by the number of component supply reels R holding the target components Ct. In the exemplary case shown in FIG. 12B, the stock quantity of the component supply reel R for the target component Ct in each of the component storages 2A, 2B, 2C, and 2D is two.

In Step S306, the arithmetic operation part 11 specifies the division D(3) on which the target component Ct is to be set, from among the plurality of divisions D(1) to D(4), on the basis of the setup information and calculates the ideal number of the target component Ct in each of the component storages 2A to 2D on the basis of the division D(3) on which the target component Ct is to be set. Then, in Step S307, the arithmetic operation part 11 sets the priorities for the component storages 2A to 2D on the basis of the difference (=stock quantity−ideal number) between the stock quantity and the ideal number (FIG. 12C).

FIG. 12C is a view schematically showing a setting example of the priority based on the difference between the stock quantity and the ideal number in the component storage. In the third warehousing support, the planned numbers of component supply reel R holding the target components Ct to be set on each of the divisions D(1) to D4) are respectively set as the ideal numbers of the component storages 2A to 2D corresponding to the divisions D(1) to D(4). Specifically, in the exemplary case shown in FIG. 12C, four component supply reels R holding the target components Ct are planned to be set on the division D(3) and the ideal number of the target component Ct in the component storage 2C corresponding to the division D(3) is set to 4. Further, since no target component Ct is planned to be set on each of the other divisions D(1), D(2), and D(4), the ideal number of the target component Ct in each of the component storages 2A, 2B, and 2D corresponding to the divisions D(1), D(2), and D(4), respectively, is set to 0. Then, the respective differences between the stock quantity and the ideal number of the component storages 2A, 2B, 2C, and 2D are obtained as 2, 2, −2, and 2, and as the value obtained by subtracting the ideal number from the stock quantity in the component storage 2 becomes smaller, in other words, as a shortage of the stock quantity relative to the ideal number in the component storage 2 becomes larger, higher priority is set to the component storage 2. As a result, the respective priorities of the component storages 2A, 2B, 2C, and 2D are 2, 2, 1, and 2. In other words, the information shown in FIG. 12C corresponds to the warehousing destination candidate information Ic indicating a candidate of the warehousing destination of the target component Ct among the plurality of component storages 2A to 2D, and this warehousing destination candidate information Ic is calculated by the arithmetic operation part 11 in the above-described procedure and stored into the storage part 12.

In Step S308, the arithmetic operation part 11 creates the support screen used for supporting the warehousing by the operator, on the basis of the warehousing destination candidate information Ic, and displays the support screen on the display of the UI 13 (FIG. 12D). FIG. 12D is a view schematically showing an example of the support screen in the third warehousing support. This support screen shows an arithmetic operation result obtained in Steps S305 and S307, and specifically, displays the ideal number and the stock quantity of the target component Ct in each of the component storages 2A to 2D and the priorities of the component storages 2A to 2D as the warehousing destination of the target component Ct.

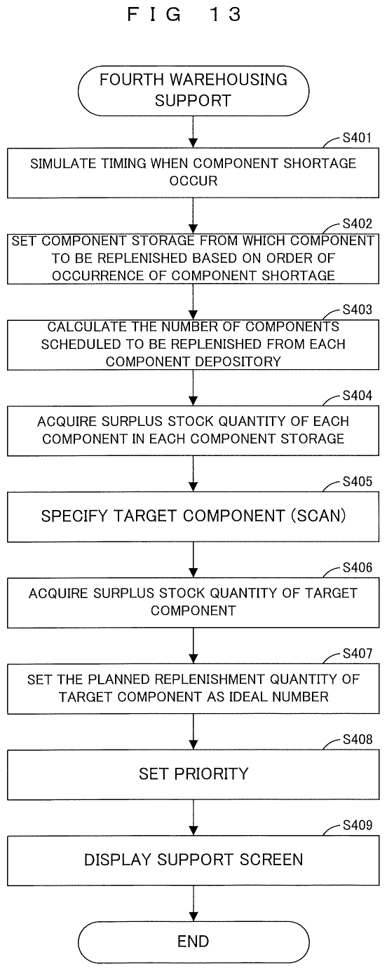

FIG. 13 is a flowchart showing the fourth warehousing support executed in the component warehousing support shown in FIG. 10. The fourth warehousing support is executed after completion of the third warehousing support. In Step S401, in a case where the component-mounted board is produced in accordance with the production plan information Ia in the component mounting system MS, a timing when the components C held by the component supply reels R set at the reel setting positions S are completely used (i.e., a timing when the component shortage occurs) is simulated by the arithmetic operation part 11. This simulation is performed on the condition in which the board production starts from an initial state where the component supply reel R is set at each reel setting position S of each component supply trolley 4, on the basis of the setup information included in the production plan information Ia. Further, this simulation is performed on the condition in which every time when a component shortage occurs in the component supply reel R, a new component supply reel R is replenished at the reel setting position S for this component supply reel R.

In Step S402, the arithmetic operation part 11 sets the component storage 2 from which the component C to be replenished (i.e., a component C of the same type as that of the component C in short supply) is planned to be delivered in response to the occurrence of the component shortage, on the basis of the order of occurrence of the component shortage. Specifically, the arithmetic operation part 11 sets the components C to be stored in each of the plurality of component storages 2 on the basis of a storage plan defining that two component supply reels R to be replenished at the reel setting positions S in response to two-times component shortages expected to occur in succession are stored in different component storages 2 in advance.

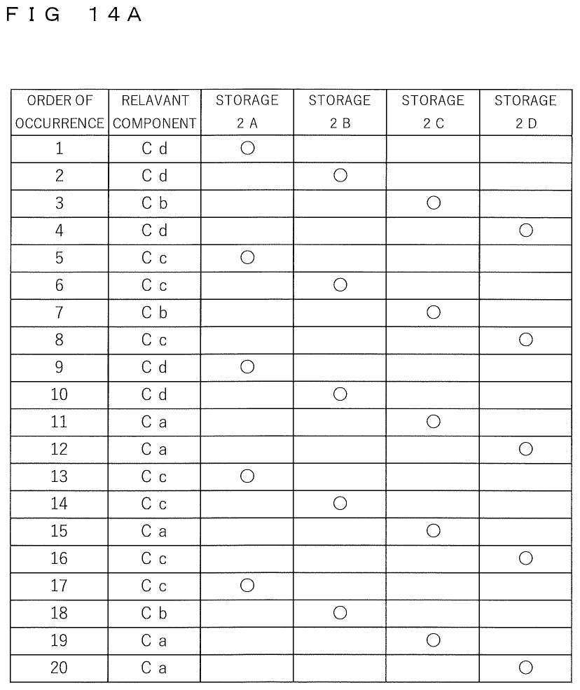

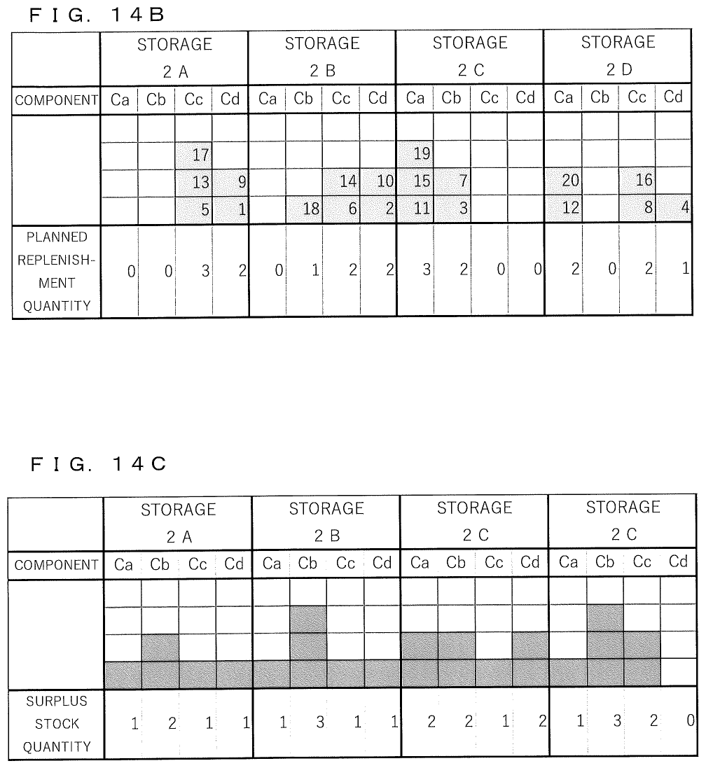

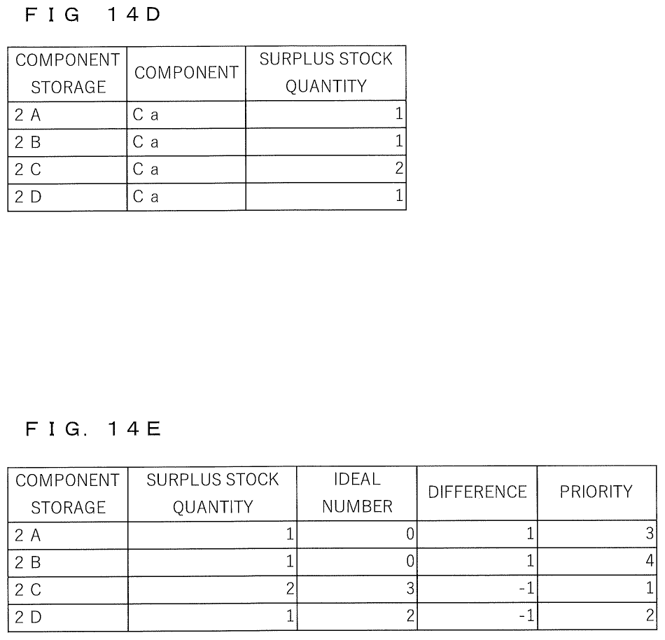

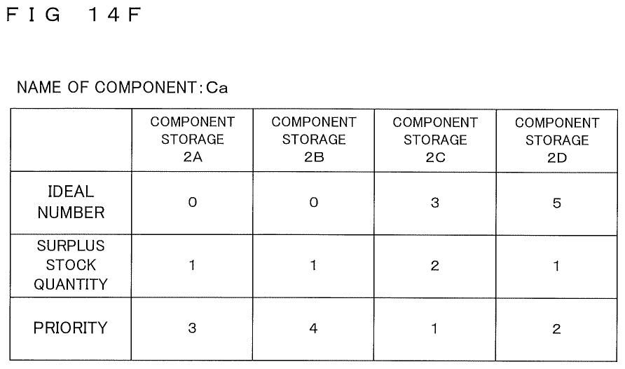

FIG. 14A is a view schematically showing an exemplary case of setting a storage destination of the component on the basis of a storage plan in accordance with the order of occurrence of the component shortage. In the exemplary case shown in FIG. 14A, a storage destination of the component C to be replenished in response to the component shortage is set in the order of the component storages 2A, 2B, 2C.amd 2D corresponding to the order of occurrence of the component shortage. Specifically, the component storage 2A is set as the storage destination for the component Cd to be replenished in response to the first occurrence of the component shortage, the component storage 2B is set as the storage destination for the component Cd to be replenished in response to the second occurrence of the component shortage, the component storage 2C is set as the storage destination for the component Cb to be replenished in response to the third occurrence of the component shortage, and the component storage 2D is set as the storage destination for the component Cd to be replenished in response to the fourth occurrence of the component shortage. Further, the component storage 2A is set as the storage destination for the component Cc to be replenished in response to the fifth occurrence of the component shortage, and thus the storage destination is set circularly among the component storages 2A, 2B, 2C, and 2D.

Thus, when the component storage 2 is set to store the component C to be replenished in accordance with the order of occurrence of the component shortage in Step S402 (FIG. 14A), in Step S403, the arithmetic operation part 11 calculates the number (a planned replenishment quantity) of the components C to be replenished from each of the component storages 2A to 2D in response to the occurrence of the component shortage (FIG. 14B).

FIG. 14B is a view schematically showing an example of the number of components planned to be replenished from the plurality of component storages. In accordance with the exemplary case shown in FIG. 14A, the respective numbers of components Ca to Cd (the number of component supply reels R) to be stored in the component storages 2A to 2D are shown in FIG. 14B. For example, the components Cc to be replenished in response to the fifth, thirteenth, and seventeenth component shortages and the components Cd to be replenished in response to the first and ninth component shortages are components to be stored in the component storage 2A in advance. In other words, as shown in the row of “Planned Replenishment Quantity” of FIG. 14B, from the component storage 2A, three component supply reels R holding the components Cc and two component supply reels R holding the components Cd are planned to be replenished. As to each of the other component storages 2B to 2D, the respective planned replenishment quantities of the components Ca to Cd are also calculated in the same manner.

In Step S404, the arithmetic operation part 11 acquires a surplus stock quantity of each of the components Ca to Cd in each of the component storages 2A to 2D (FIG. 14C). FIG. 14C is a view schematically showing an example of the surplus stock quantity of the component in each of the plurality of component storages. As shown in FIG. 14C, the arithmetic operation part 11 acquires the surplus stock quantity of each of the components Ca to Cd in each of the component storages 2A to 2D. The surplus stock quantity is obtained by subtracting a planned usage quantity in the setup operation from the actual stock quantity in the component storage 2. The arithmetic operation part 11 can check the actual stock quantity, for example, on the basis of the stock information Ib and check the planned usage quantity in the setup operation on the basis of the setup information included in the production plan information Ia. In the exemplary case shown in FIG. 14C, the respective surplus stock quantities of the components Ca, Cb, Cc, and Cd in the component storage 2A are 1, 2, 1, and 1. As to each of the other component storages 2B to 2D, the respective surplus stock quantities of the components Ca to Cd are also acquired in the same manner.

In Step S405, the arithmetic operation part 11 specifies the target component Ca to be warehoused on the basis of the component ID read by the scanner 26. The arithmetic operation part 11 can thereby recognize the type of target component Ca. In Step S406, the arithmetic operation part 11 acquires the surplus stock quantity of the target component Ca on the basis of the result (FIG. 14C) acquired in Step S404 (FIG. 14D).

FIG. 14D is a view schematically showing the surplus stock quantity of the target component in each component storage. In FIG. 14D, the surplus stock quantity of the target component Ca is represented by the number of component supply reels R holding the target components Ca. In the exemplary case shown in FIG. 14D, the respective surplus stock quantities of the component supply reels R for the target components Ca in the component storages 2A, 2B, 2C, and 2D are 1, 1, 2, and 1.

In Step S407, the arithmetic operation part 11 sets the planned replenishment quantity of the target component Ca from each of the component storages 2A to 2D as the ideal number of the target component Ca in the component storage 2A to 2D. Specifically, the planned replenishment quantity of the target component Ca obtained from the result (FIG. 14B) calculated in Step S403 is set as the ideal number. Then, in Step S408, the priority is set for each of the component storages 2A to 2D on the basis of the difference (=surplus stock quantity−ideal number) between the surplus stock quantity and the ideal number (FIG. 14E).

FIG. 14E is a view schematically showing a setting example of the priority based on the difference between the surplus stock quantity and the ideal number of the target component in the component storage. In the exemplary case shown in FIG. 14E, the respective differences between the surplus stock quantity and the ideal number of the target component Ca in the component storages 2A, 2B, 2C, and 2D are calculated as 1, 1, −1, and −1, and as the value obtained by subtracting the ideal number from the surplus stock quantity in the component storage 2 becomes smaller, in other words, as a shortage of the surplus stock quantity relative to the ideal number in the component storage 2 becomes larger, higher priority is set to the component storage 2. As a result, the respective priorities of the component storages 2A, 2B, 2C, and 2D are 3, 4, 1, and 2. Further, as to the priorities of the plurality of component storages 2 having the same difference, as the order in which the surplus stock is exhausted in the component storage 2 is earlier, higher priority is set to the component storage 2. Specifically, as to the component storages 2C and 2D having the same difference of “4”, the timing when the target component Ca is exhausted in the component storages 2C is the nineteenth component shortage while the timing when the target component Ca is exhausted in the component storages 2D is the twentieth component shortage (FIG. 14B). Then, the priority of the component storage 2C is set higher than that of the component storage 2D. Thus, the information shown in FIG. 14E corresponds to the warehousing destination candidate information Ic indicating a candidate of the warehousing destination of the target component Ca among the plurality of component storages 2A to 2D, and this warehousing destination candidate information Ic is calculated by the arithmetic operation part 11 in the above-described procedure and stored into the storage part 12.

In Step S409, the arithmetic operation part 11 creates the support screen to be used for supporting the warehousing by the operator, on the basis of the warehousing destination candidate information Ic, and displays the support screen on the display of the UI 13 (FIG. 14F). FIG. 14F is a view schematically showing an example of the support screen in the fourth warehousing support. This support screen displays an arithmetic operation result obtained in Steps S406 to S408, and specifically displays the ideal number and the surplus stock quantity of the target component Ca in each of the component storages 2A to 2D and the priorities of the component storages 2A to 2D as the warehousing destination of the target component Ca.

In the above-described embodiment, the stock quantity (surplus stock quantity) indicating the number of target components Ct or Ca to be warehoused, which are actually stored in each of component storages 2A to 2D, is acquired for each of the plurality of component storages 2A to 2D (Steps S305 and S406). Then, the warehousing destination candidate information Ic indicating a candidate of the warehousing destination of the target component Ct or Ca from among the plurality of component storages 2A to 2D is calculated on the basis of the stock quantity (surplus stock quantity) of the target component Ct or Ca in each of the plurality of component storages 2A to 2D (Steps S306 to S407 and S407 to S408). Therefore, it is possible to check the candidate of the warehousing destination in accordance with the stock quantity (surplus stock quantity) of the target component Ca or Ct in each of the component storages 2A to 2D, from the warehousing destination candidate information Ic. As a result, it becomes possible to easily determine an appropriate component storage 2 as the warehousing destination of the component from among the plurality of component storages 2A to 2D.

Further, the warehousing destination candidate information Ic indicates each of the plurality of component storages 2A to 2D as the candidate while giving priorities thereto, the priorities being calculated on the basis of the stock quantity (surplus stock quantity) of the target component Ct or Ca in each of the component storages 2A to 2D (FIGS. 12C and 14E). With reference to the priority of each of the plurality of component storages 2A to 2D, the warehousing destination of the target component Ct or Ca can be thereby selected from among the plurality of component storages 2A to 2D.

Further, the arithmetic operation part 11 (warehousing destination candidate calculation part) acquires the details of the setup operation (the setup information of the production plan information Ia) for setting the component supply reel R at the reel setting position S of the component supply trolley 4 which has the plurality of reel setting positions S on each of which the component supply reel R holding the component C can be set. Furthermore, the arithmetic operation part 11 divides the plurality of reel setting positions S into the plurality of divisions D(1) to D(4) corresponding to the different component storages 2A to 2D, respectively (Steps S301 to S303) and calculates the ideal number of the target component Ct in each of the component storages 2A to 2D on the basis of the number of target components Ct (the number of component supply reels R) to be set at the reel setting positions S belonging to each of the divisions D(1) to D(4) corresponding to the component storages 2A to 2D (Step S306). With such a configuration, the plurality of reel setting positions S of the component supply trolley 4 are divided into the plurality of divisions D(1) to D(4) and the divisions D(1) to D(4) are associated with different component storages 2A to 2D. Then, it is possible to warehouse the target component Ct into the component storage 2A to 2D corresponding to the division D(1) to D(4) including the reel setting position S at which the target component Ct is to be set. For this reason, it is possible to deliver the components C to be set on the component supply trolley 4 in the setup operation, from the plurality of component storages 2A to 2D in parallel. Therefore, it is possible to complete the delivery of each component C required for the setup operation in a short time.

Further, the arithmetic operation part 11 (warehousing destination candidate calculation part) simulates the timing when the component shortage occurs when the component C held by the component supply reel R (component holding member) is supplied by each of the plurality of tape feeders (feeders) 5 and mounted on the board B (Step S401). Furthermore, the arithmetic operation part 11 calculates the ideal number of the target component Ca in the component storage 2 on the basis of the result obtained by calculating the number of components C to be stored in each of the component storages 2, on the basis of the plan for storing in advance two component supply reels R to be replenished to the tape feeder 5 in accordance with two-times component shortages which are expected to occur in succession, in different component storages 2 (Steps S402 to S404 and S407). With such a configuration, it is possible to avoid such a condition in which the delivery of each component C of which shortage occurs in succession is requested to the same component storage 2 and the delivery of the components C is delayed.

Thus, in the above-described embodiment, the server computer 1 corresponds to one example of a “component warehousing support apparatus” of the present disclosure, each of the component storages 2 and 2A to 2D corresponds to one example of a “component storage” of the present disclosure, the arithmetic operation part 11 corresponds to one example of a “stock quantity acquisition part” and a “warehousing destination candidate calculation part” of the present disclosure, the UI 13 corresponds to one example of a “display part” of the present disclosure, the recording medium 19 corresponds to one example of a “recording medium” of the present disclosure, the tape feeder 5 corresponds to one example of a “feeder” of the present disclosure, the board B corresponds to one example of a “board” of the present disclosure, the component C corresponds to one example of a “component” of the present disclosure, each of the divisions D(1) to D(4) corresponds to one example of a “division” of the present disclosure, the warehousing destination candidate information Ic corresponds to one example of “warehousing destination candidate information” of the present disclosure, each of the production plans PL1 to PL3 corresponds to one example of a “production plan” of the present disclosure, the component warehousing support program Px corresponds to one example of a “component warehousing support program” of the present disclosure, the component supply reel R corresponds to one example of a “component holding member” of the present disclosure, and the reel setting position S corresponds to one example of a “component setting position” of the present disclosure.

Further, the present disclosure is not limited to the above-described embodiment, and numerous modifications and variations can be added to those described above without departing from the scope of the disclosure. For example, in the above-described embodiment, the warehousing destination candidate information Ic indicates each of the plurality of component storages 2A to 2D as the candidate of the warehousing destination while giving priorities thereto. The warehousing destination candidate information Ic, however, may be configured so as to indicate one optimal component storage 2 (i.e., the component storage 2 having the highest priority) as the candidate of the warehousing destination among the plurality of component storages 2A to 2D. With such a configuration, it is possible to easily determine one optimal component storage 2 as the warehousing destination of the component among the plurality of component storages 2A to 2D. Further, in this variation, the support screen displayed on a display of the UI 13 shows only the one optimal component storage 2 as the warehousing destination of the component C.

Furthermore, in the first warehousing support, in such a support as to uniformly warehouse the components C into the component storages 2A to 2D, it is not indispensable to use the difference between the ideal number and the stock quantity of the target component Ct in each of the component storages 2A to 2D. For example, as the stock quantity of the target component Ct in the component storage 2 becomes smaller, higher priority may be given to the component storage 2.

Further, the warehousing destination candidate information Ic has only to be information indicating the candidate of the warehousing destination of the target component Ct among the plurality of component storages 2 and does not always need to include the stock quantity, the ideal number, or the difference therebetween as shown in FIGS. 6B and 9B.

Furthermore, in the above-described embodiment, the four component storages 2 provided in the component mounting system MS correspond to “a plurality of component storages” of the present disclosure. The above-described embodiment may be applied, however, by handling some (e.g., three) of the four component storages 2 as “the plurality of component storages” of the present disclosure.

Further, the subject who determines the warehousing destination of the component does not always need to be the operator but may be a work robot which performs warehousing and delivery into/from the component storage 2. In this case, the warehousing destination candidate information Ic is transmitted from the server computer 1 to the work robot and the work robot determines the warehousing destination of the component C on the basis of the received warehousing destination candidate information Ic.

Furthermore, the component C to be warehoused into the component storage 2 is not limited to the component C held by the component supply reel R but may be a component C (tray component) held by a tray.

What is claimed is:

1. A component warehousing support apparatus that supports warehousing of a component into each of a plurality of component storages in which a warehoused component is stored and from which a component is delivered in response to a request, comprising:
processing circuitry configured to
acquire a stock quantity indicating a number of target components to be warehoused, which are actually stored in each of the component storages, for each of the plurality of component storages; and
calculate warehousing destination candidate information indicating a candidate of a warehousing destination of the target component from among the plurality of component storages, on the basis of the stock quantity of the target component in each of the plurality of component storages.

2. The component warehousing support apparatus according to claim 1, wherein
the warehousing destination candidate information indicates each of the plurality of component storages as the candidate, with priority calculated on the basis of the stock quantity of the target component in each of the plurality of component storages.

3. The component warehousing support apparatus according to claim 2, wherein
the processing circuitry is configured to determine the priority on the basis of a result obtained by calculating a difference between an ideal number which is the ideal number of target components stored in the component storages and the stock quantity of the target component, for each of the plurality of component storages.

4. The component warehousing support apparatus according to claim 3, wherein
the processing circuitry is configured to calculate an average value of the stock quantities of the target component in the plurality of component storages, as the ideal number of the target component which is common to the plurality of component storages.

5. The component warehousing support apparatus according to claim 3, wherein
the processing circuitry is configured to acquire a plurality of production plans each for producing a predetermined type of component-mounted board by mounting a component on a board, associates the plurality of production plans with different component storages, respectively, and calculate the ideal number of the target component in the component storage on the basis of the number of target components to be mounted on the boards in the production plan corresponding to the component storage.

6. The component warehousing support apparatus according to claim 3, wherein
the processing circuitry is configured to acquire details of a setup operation for setting a component at each of a plurality of component setting positions included in a component supply trolley, at each of which the component is settable, divides the plurality of component setting positions into a plurality of divisions corresponding to the different component storages, and calculate the ideal number of the target component in the component storage on the basis of the number of target components to be set at the component setting positions belonging to the division corresponding to the component storage.

7. The component warehousing support apparatus according to claim 3, wherein
the processing circuitry is configured to calculate the ideal number of the target component in the component storage on the basis of a result obtained by calculating the number of components to be stored into each of the plurality of component storages on the basis of a plan to store in advance two component holding members in different component storages, the two component holding members being to be replenished to a feeder in response to two-times component shortages expected to occur in succession when a component held by a component holding member holding a component is supplied by each of a plurality of feeders and mounted on a board.

8. The component warehousing support apparatus according to claim 1, wherein
the warehousing destination candidate information indicates one optimal component storage as the candidate of the warehousing destination among the plurality of component storages.

9. The component warehousing support apparatus according to claim 1, further comprising:
a display configured to display the candidate of the warehousing destination of the target component, which is indicated by the warehousing destination candidate information, from among the plurality of component storages, to an operator.

10. A component warehousing support method for supporting warehousing of a component into each of a plurality of component storages in which a warehoused component is stored and from which the component is delivered in response to a request, comprising:
acquiring, by processing circuitry, a stock quantity indicating the number of target components to be warehoused, which are actually stored in each of the component storages, for each of the plurality of component storages; and
calculating, by the processing circuitry, warehousing destination candidate information indicating a candidate of a warehousing destination of the target component from among the plurality of component storages, on the basis of the stock quantity of the target component in each of the plurality of component storages.

11. A non-transitory computer readable medium storing a component warehousing support program for supporting warehousing of a component into each of a plurality of component storages in which a warehoused component is stored and from which the component is delivered in response to a request, which causes a computer to execute the processes of:
acquiring a stock quantity indicating the number of target components to be warehoused, which are actually stored in each of the component storages, for each of the plurality of component storages; and
calculating warehousing destination candidate information indicating a candidate of a warehousing destination of the target component from among the plurality of component storages, on the basis of the stock quantity of the target component in each of the plurality of component storages.

12. (canceled)

13. The component warehousing support apparatus according to claim 2, further comprising:
a display configured to display the candidate of the warehousing destination of the target component, which is indicated by the warehousing destination candidate information, from among the plurality of component storages, to an operator.

14. The component warehousing support apparatus according to claim 3, further comprising:
a display configured to display the candidate of the warehousing destination of the target component, which is indicated by the warehousing destination candidate information, from among the plurality of component storages, to an operator.

15. The component warehousing support apparatus according to claim 4, further comprising:
a display configured to display the candidate of the warehousing destination of the target component, which is indicated by the warehousing destination candidate information, from among the plurality of component storages, to an operator.

16. The component warehousing support apparatus according to claim 5, further comprising:
a display configured to display the candidate of the warehousing destination of the target component, which is indicated by the warehousing destination candidate information, from among the plurality of component storages, to an operator.

17. The component warehousing support apparatus according to claim 6, further comprising:
a display configured to display the candidate of the warehousing destination of the target component, which is indicated by the warehousing destination candidate information, from among the plurality of component storages, to an operator.

18. The component warehousing support apparatus according to claim 7, further comprising:
a display configured to display the candidate of the warehousing destination of the target component, which is indicated by the warehousing destination candidate information, from among the plurality of component storages, to an operator.

19. The component warehousing support apparatus according to claim 8, further comprising:
a display configured to display the candidate of the warehousing destination of the target component, which is indicated by the warehousing destination candidate information, from among the plurality of component storages, to an operator.
